(19) United States
(12) Patent Application Publication
(10) Pub. No.: US 2026/0018451 A1
(43) Pub. Date: Jan. 15, 2026

(54) ADHESIVE TAPE SHEET, METHOD OF MANUFACTURING THE SAME AND METHOD OF MANUFACTURING SEMICONDUCTOR DEVICES USING THE SAME

(71) Applicant: Samsung Electronics Co., Ltd., Suwon-si (KR)

(72) Inventor: Hyungjun Kim, Suwon-si (KR)

(21) Appl. No.: 19/079,894

(22) Filed: Mar. 14, 2025

(30) Foreign Application Priority Data
Jul. 11, 2024 (KR) 10-2024-0091434

(51) Int. Cl. H01L 21/683; C09J 121/00

(52) U.S. Cl. CPC H01L 21/6836; C09J 121/00; H01L 2221/68386

(57) ABSTRACT

An adhesive tape sheet includes an adhesive film including a first region attached to a semiconductor structure and vertically overlapping an edge of the semiconductor structure, and a second region adjacent to the first region. The adhesive film includes a non-patterned portion and a plurality of pattern portions defined by incision portions. A portion of the plurality of pattern portions include an open portion connected to the non-patterned portion in a first direction, and an extension portion having at least a portion extending from the open portion in a second direction opposite to the first direction and defined by the incision portions. A first group of the plurality of pattern portions are disposed on the first region and a second group of the plurality of pattern portions are disposed on the second region. A first density of the first group and a second density of the second group are different.

### CROSS-REFERENCE TO RELATED APPLICATION(S)

This application claims the benefit of priority under 35 U.S.C. § 119 to Korean Patent Application No. 10-2024-0091434 filed on Jul. 11, 2024 in the Korean Intellectual Property Office, the disclosure of which is incorporated herein by reference in its entirety.

### BACKGROUND

Example embodiments of the present disclosure relate to an adhesive tape sheet, a method of manufacturing the same and a method of manufacturing a semiconductor device using the same.

As electronic devices have been designed to have a reduced weight and high-performance, research and development of semiconductor devices having a reduced size, high-performance, and high reliability have been continuously conducted.

### SUMMARY

An example embodiment of the present disclosure is to provide an adhesive tape sheet including a plurality of patterns formed therein.

According to an example embodiment of the present disclosure, an adhesive tape sheet includes an adhesive film including a first region to which a semiconductor structure is attached and which vertically overlaps an edge of the semiconductor structure and a second region adjacent to the first region, wherein the adhesive film includes a non-patterned portion; and a plurality of pattern portions defined by incision portions, wherein at least a portion of the plurality of pattern portions include an open portion connected to the non-patterned portion in a first direction; and an extension portion having at least a portion extending from the open portion in a second direction opposite to the first direction and defined by the incision portions, wherein a first group of the plurality of pattern portions are disposed on the first region and a second group of the plurality of pattern portions are disposed on the second region, and wherein a first density of the first group of the plurality of pattern portions and a second density of the second group of the plurality of pattern portions are different.

According to an example embodiment of the present disclosure, an adhesive tape sheet includes an adhesive film including a non-patterned region and a pattern region having adhesion patterns defined by incision patterns, wherein each of the incision patterns defines the adhesion patterns such that at least one side of each of the adhesion patterns is continuous with the non-patterned region and each of the other sides of the adhesion patterns is discontinuous with the non-patterned region, and wherein the pattern region includes a first region in which the adhesion patterns are disposed at a first density; and a second region in which the adhesion patterns are disposed at a second density different from the first density.

According to an example embodiment of the present disclosure, an adhesive tape sheet includes an adhesive film comprising a plurality of pattern portions defined by non-patterned portions and incision portions, wherein at least a portion of the plurality of pattern portions of the adhesive film comprises an open portion connected to the non-patterned portion in a first direction and an extension portion extending from the open portion in a second direction opposite to the first direction and defined by the incision portions, and wherein the adhesive film includes an elastic polymer.

According to an example embodiment of the present disclosure, a method of manufacturing a semiconductor device includes providing a first preliminary semiconductor structure on a first adhesive tape sheet; and forming a second preliminary semiconductor structure by performing a first semiconductor process on the first preliminary semiconductor structure, wherein the first adhesive tape sheet includes a first non-patterned portion; and a plurality of first pattern portions defined by first incision portions, wherein at least a portion of the plurality of first pattern portions includes a first open portion connected to the first non-patterned portion in a first direction; and a first extension portion having at least a portion extending from the first open portion in a second direction opposite to the first direction and defined by the first incision portions.

According to an example embodiment of the present disclosure, a method of manufacturing a semiconductor device is provided, wherein the first preliminary semiconductor structure comprises a first surface and a second surface opposite to the first surface, and to which a carrier substrate is attached, and wherein the providing a first preliminary semiconductor structure comprises bonding the first surface of the first preliminary semiconductor structure to the first adhesive tape sheet.

According to an example embodiment of the present disclosure, a method of manufacturing a semiconductor device is provided, wherein the first adhesive tape sheet has a first region in which the plurality of first pattern portions have a relatively high density, and wherein the bonding comprises allowing an edge of the first preliminary semiconductor structure to perpendicularly overlap the first region of the first adhesive tape sheet.

According to an example embodiment of the present disclosure, a method of manufacturing a semiconductor device is provided, wherein the first semiconductor process comprises removing the carrier substrate from the second surface of the first preliminary semiconductor structure to expose the second surface, and wherein the removing the carrier substrate comprises removing the carrier substrate in the first direction.

According to an example embodiment of the present disclosure, a method of manufacturing a semiconductor device is provided, wherein each of the first extension portions of the plurality of first pattern portions comprises: a first side and a second side each extending in a second direction from both ends of the first open portion and opposing each other; and a third side connecting the first side to the second side and opposing the first open portion.

According to an example embodiment of the present disclosure, a method of manufacturing a semiconductor device further comprises forming a third preliminary semiconductor structure by performing a second semiconductor process on the first adhesive tape sheet and the second preliminary semiconductor structure; and providing the third preliminary semiconductor structure on a second adhesive tape sheet, wherein the second adhesive tape sheet comprises: a second non-patterned portion; and a plurality of second pattern portions defined by second incision portions, wherein at least a portion of the plurality of second pattern portions comprises: a second open portion connected to the second non-patterned portion in a third direction; and a second extension portion having at least a portion extending from the second open portion in a fourth direction opposite to the third direction and defined by the second incision portions.

According to an example embodiment of the present disclosure, a method of manufacturing a semiconductor device is provided, wherein the second semiconductor process comprises dicing the first adhesive tape sheet along an edge of the second preliminary semiconductor structure, wherein the providing the third preliminary semiconductor structure to the second adhesive tape sheet comprises bonding the second surface of the third preliminary semiconductor structure to the second adhesive tape sheet after the dicing.

According to an example embodiment of the present disclosure, a method of manufacturing a semiconductor device is provided, wherein the providing the third preliminary semiconductor structure to the second adhesive tape sheet is performed such that the first direction and the third direction are directed in opposite directions.

According to an example embodiment of the present disclosure, a method of manufacturing a semiconductor device further comprises removing the first adhesive tape sheet from the third preliminary semiconductor structure, wherein the removing the first adhesive tape sheet comprises removing the first adhesive tape sheet in the third direction with respect to the second adhesive tape sheet.

According to an example embodiment of the present disclosure, a method of manufacturing a semiconductor device further comprises removing the first adhesive tape sheet from the third preliminary semiconductor structure, wherein the removing the first adhesive tape sheet comprises removing the first adhesive tape sheet in the second direction.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a vertical cross-sectional diagram illustrating an adhesive tape sheet according to an example embodiment of the present disclosure;

FIG. 2 is a plan diagram illustrating an adhesive tape sheet according to an example embodiment of the present disclosure;

FIG. 3A is an enlarged diagram illustrating a portion of an adhesive tape sheet according to an example embodiment of the present disclosure;

FIGS. 3B and 3C are enlarged diagrams illustrating a portion of an adhesive tape sheet according to an example embodiment of the present disclosure;

FIG. 4 is an enlarged diagram illustrating an adhesive tape sheet according to an example embodiment of the present disclosure;

FIGS. 5A to 5E are enlarged diagrams illustrating a portion of an adhesive tape sheet according to an example embodiment of the present disclosure;

FIG. 6 is a perspective diagram illustrating an adhesive tape sheet according to an example embodiment of the present disclosure;

FIG. 7 is an enlarged diagram illustrating a portion of an adhesive tape sheet according to an example embodiment of the present disclosure;

FIG. 8 is a perspective diagram illustrating an adhesive tape sheet according to an example embodiment of the present disclosure;

FIG. 9 is an enlarged diagram illustrating a portion of an adhesive tape sheet according to an example embodiment of the present disclosure;

FIG. 10 is an enlarged diagram illustrating a portion of an adhesive tape sheet according to an example embodiment of the present disclosure;

FIG. 11 is an enlarged diagram illustrating a portion of an adhesive tape sheet according to an example embodiment of the present disclosure;

FIG. 12 is an enlarged diagram illustrating a portion of an adhesive tape sheet according to an example embodiment of the present disclosure;

FIG. 13 is a perspective diagram illustrating a method of manufacturing an adhesive tape sheet according to an example embodiment of the present disclosure;

FIG. 14 is a flowchart illustrating processes of a method of manufacturing a semiconductor device using an adhesive tape sheet in order according to an example embodiment of the present disclosure;

FIG. 15 is a flowchart illustrating processes of a method of manufacturing a semiconductor device using an adhesive tape sheet in order according to an example embodiment of the present disclosure;

FIGS. 16 to 20 are vertical cross-sectional diagrams illustrating a method of manufacturing a semiconductor device using an adhesive tape sheet according to an example embodiment of the present disclosure;

FIG. 21 is a flowchart illustrating processes of a method of manufacturing a semiconductor device using an adhesive tape sheet in order according to an example embodiment of the present disclosure; and

FIGS. 22 to 26 are vertical cross-sectional diagrams illustrating a method of manufacturing a semiconductor device using an adhesive tape sheet according to an example embodiment of the present disclosure.

### DETAILED DESCRIPTION

Hereinafter, embodiments of the present disclosure will be described as follows with reference to the accompanying drawings.

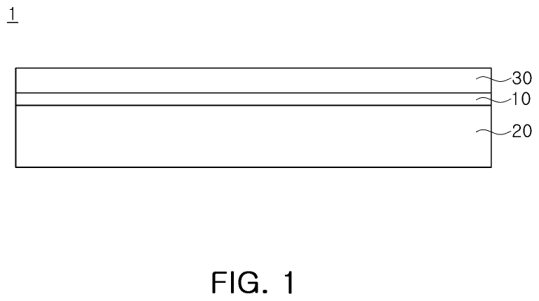

FIG. 1 is a vertical cross-sectional diagram illustrating an adhesive tape sheet according to an example embodiment.

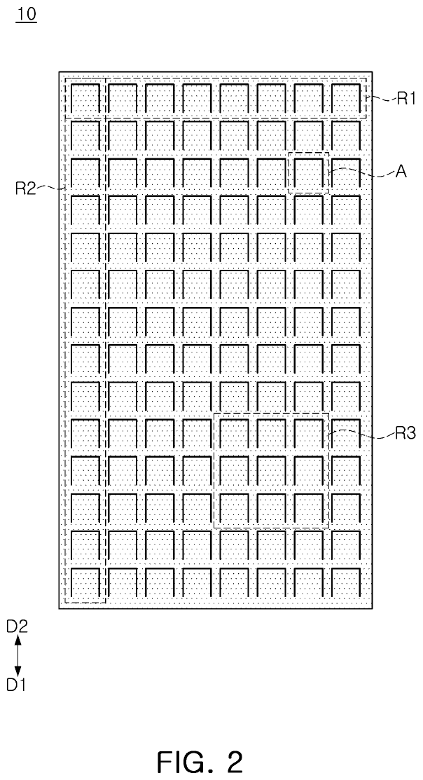

FIG. 2 is a plan diagram illustrating an adhesive tape sheet according to an example embodiment.

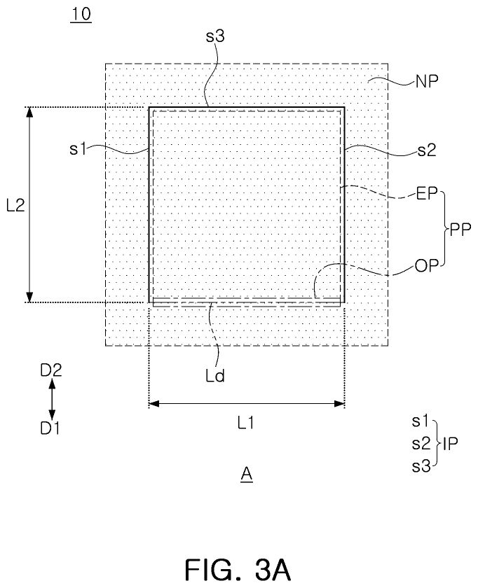

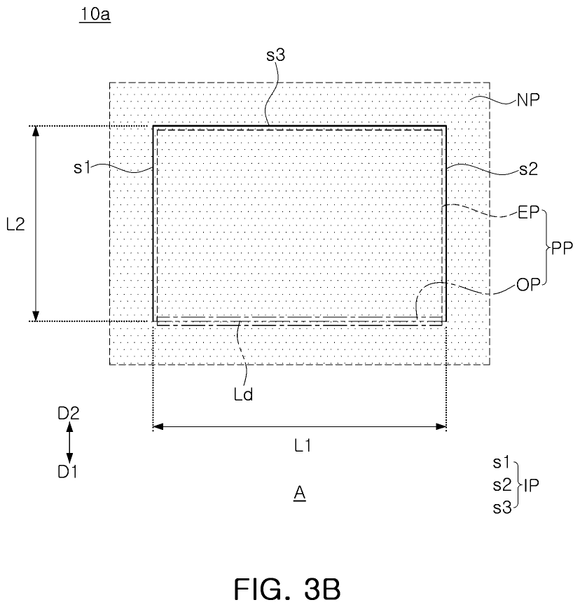

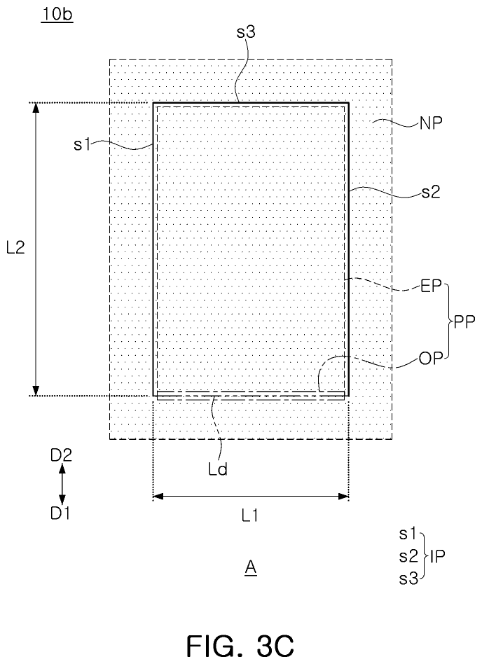

FIG. 3A is an enlarged diagram illustrating a portion of an adhesive tape sheet according to an example embodiment, illustrating region “A” in FIG. 2.

Referring to FIG. 1, an adhesive tape sheet 1 may include a substrate layer 20, an adhesive layer 10 on the substrate layer 20, and a cover layer 30 on the adhesive layer 10. The substrate layer 20 may be implemented as a substrate film, the adhesive layer 10 may be referred to as an adhesive film, and the cover layer 30 may be referred to as a cover film.

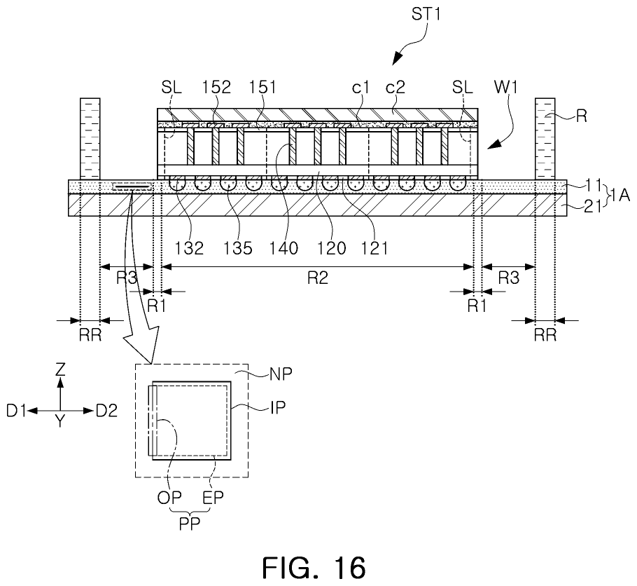

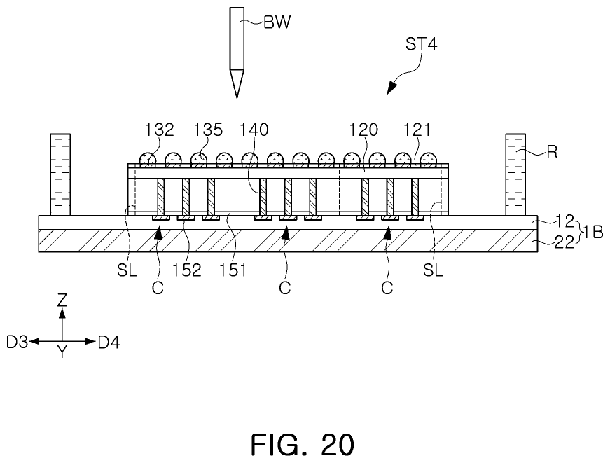

The adhesive tape sheet 1 may be attached to an adherend and may protect or support the adherend. The adhesive tape sheet 1 may be implemented as a tape sheet used in a semiconductor process, but an example embodiment thereof is not limited thereto. When the adhesive tape sheet 1 is used in the semiconductor process, the adherend may be implemented as a semiconductor wafer W or a chip C (for example, “W1” in FIG. 16, “C” in FIG. 20). For ease of description, the example in which the adhesive tape sheet 1 is used in a semiconductor process will be described.

The adhesive layer 10 may be attached to the adherend and may protect or support the adherend.

In an example embodiment, the adhesive layer 10 may prevent damage or contamination when the adherend is moved or processed. The adhesive layer 10 may protect one surface of the adherend by, for example, preventing scratches and debris from being imparted onto the adherend while the adherend being transported and handled.

In an example embodiment, the adhesive layer 10 may be a dicing tape for fixing the semiconductor wafer in a process of cutting the semiconductor wafer into individual chips. The adhesive layer 10 may enable a dicing blade to accurately cut the semiconductor wafer.

In an example embodiment, the adhesive layer 10 may fix and protect the semiconductor chip in a process of packaging the semiconductor chip.

In an example embodiment, the adhesive layer 10 may not require UV curing during the semiconductor process.

In an example embodiment, when the adhesive layer 10 is removed from the adherend, residues derived from the adhesive layer 10 may not remain on the adherend.

In an example embodiment, the adhesive layer 10 may be reused after the semiconductor process is performed.

The adhesive layer 10 may include a material suitable for the above-described purposes. The adhesive layer 10 may include a material having excellent flexibility, chemical resistance, and heat resistance. The adhesive layer 10 may include a soft elastomer or an elastomeric polymer. The adhesive layer 10 may include, for example, at least one of a silicone elastomer, a polyurethane elastomer, an ethylene propylene diene monomer (EPDM) elastomer, a polybutadiene elastomer, and a nitrile butadiene rubber. Throughout the specification, when a component is described as “including” or “may include” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

The thickness of the adhesive layer 10 may be 100 μm or less. In an example embodiment, the thickness of the adhesive layer 10 may be in a range of 5 μm or more and 100 μm or less.

The substrate layer 20 may be disposed on one surface (e.g., a first surface) of the adhesive layer 10 and may be implemented as a support for supporting the adhesive layer 10. The substrate layer 20 may provide structural stability of the adhesive layer 10. The substrate layer 20 may provide stability which may, for example, maintain a physical form of the adhesive layer 10 and may withstand mechanical forces applied externally. The substrate layer 20 may provide thermal and chemical resistance to withstand various environmental conditions of the semiconductor process.

The substrate layer 20 may include a material suitable for the above-described purpose. The substrate layer 20 may include a material having excellent flexibility, chemical resistance, and heat resistance. The substrate layer 20 may include, for example, polyimide (PI), polyester (PET), polyurethane (PU), polyvinyl chloride (PVC), and polyolefin (PO).

A thickness of the substrate layer 20 may be 100 μm or less. In an example embodiment, a thickness of the substrate layer 20 may be in a range of 25 μm or more and 100 μm or less.

The cover layer 30 may be a cover film disposed on the other surface (e.g., a second surface) opposite to the one surface of the adhesive layer 10 and covering the other surface of the adhesive layer 10. The cover layer 30 may protect the adhesive layer 10 from being in contact with an external environment. The cover layer 30 may protect the adhesive layer 10 from, for example, dust, contaminants, moisture, or the like.

The cover layer 30 may include a material suitable for the above-described purposes. The cover layer 30 may include a material having excellent chemical resistance and heat resistance and easily isolated from the adhesive layer 10. The cover layer 30 may include, for example, polyethylene (PE), polypropylene (PP), polyester (PET), and a silicone-treated film.

A thickness of the cover layer 30 may be 50 μm or less. In an example embodiment, the thickness of the cover layer 30 may be in a range of 30 μm or more and 50 μm or less.

The adhesive tape sheet 1 may be provided in a state in which the cover layer 30 covers the adhesive layer 10. The cover layer 30 may be separated from the adhesive layer 10 such that one surface of the adhesive layer 10 is exposed, and the exposed surface of the adhesive layer 10 may be attached to the adherend.

The adhesive tape sheet 1 may be provided as the substrate layer 20 and the adhesive layer 10. For example, the adhesive tape sheet 1 may be provided with the substrate layer 20 and the adhesive layer 10 without the cover layer 30.

Referring to FIGS. 2 and 3A, the adhesive layer 10 may include a non-patterned portion NP and a plurality of pattern portions PP.

Each of the plurality of pattern portions PP may be defined by an incision portion IP. The incision portion IP may be a portion or a region defining the pattern portion PP and dividing the adhesive layer 10 into the non-patterned portion NP and the pattern portion PP. The non-patterned portion NP may refer to a portion other than the plurality of pattern portions PP. For example, the non-patterned portion NP may refer to a portion not defined by the incision portion IP. Accordingly, the side surface of the non-patterned portion NP and the side surface of the adhesive layer 10 may be aligned. In example embodiments, the incision portion IP may be referred to as an incision pattern, and the pattern portion PP may be referred to as an adhesion pattern.

At least one side of the pattern portion PP may be physically connected to the non-patterned portion NP in one direction. The pattern portion PP may be defined to have an open portion OP and an extension portion EP.

The open portion OP may be defined as a portion or a local region including a boundary portion Ld separating the pattern portion PP from the non-patterned portion NP and is drawn by a dotted line. The open portion OP may be disposed between the extension portion EP of the pattern portion PP and the non-patterned portion NP and may be physically connected to the non-patterned portion NP in the first direction D1. The incision portion IP of the patterned portion PP may provide a physical separation of the extension portion EP of the patterned portion PP from the non-patterned portion NP. The open portion OP of the patterned portion PP may provide a physical connection of the extension portion EP of the patterned portion PP to the non-patterned portion NP. The physical connection provided by the open portion OP is shown in FIG. 3A as the boundary portion Ld.

The extension portion EP may be a portion or a region extending from the open portion OP in the second direction D2 opposite to the first direction D1. The extension portion EP may include a first side s1 and a second side s2 extending from both ends of the open portion OP in the second direction D2, respectively, and opposing each other. The extension portion EP may further include a third side s3 connecting the first side s1 to the second side s2 in the horizontal direction and opposing the open portion OP. The first to third sides s1, s2, and s3 of the extension portion EP may be defined by the incision portion IP.

A length in the horizontal direction and a length in the vertical direction of the pattern portion PP may be substantially the same. The length in the horizontal direction of the pattern portion PP may be defined as a length L1 in the horizontal direction of the open portion OP, and the length in the vertical direction of the pattern portion PP may be defined as a length (or a maximum length) L2 in the vertical direction of the extension portion EP. For example, the length L1 in the horizontal direction of the open portion OP and the length L2 in the vertical direction of the extension portion EP may be substantially the same.

The incision portion IP may be an incision pattern formed by penetrating the length in the thickness direction of the adhesive layer 10. The thickness of the incision portion IP may not be defined. From a planar perspective, the incision portion IP may be an open figure having an open shape not having at least one side. For example, the incision portion IP may have a profile of an incomplete polygonal shape (for example, an open polygonal shape) or an incomplete circular shape (for example, an open circular shape).

In an example embodiment, the incision portion IP may be an open square shape. The incision portion IP may have three sides formed along the first to third sides s1, s2, and s3 of the extension portion EP and four corners corresponding to the corners of the extension portion EP.

The plurality of pattern portions PP may be regularly arranged on the adhesive layer 10.

From a first perspective, the configuration in which the plurality of pattern portions PP may be regularly arranged on the adhesive layer 10 may indicate that densities of the plurality of pattern portions PP may be constant throughout the entire region of the adhesive layer 10.

The densities of the plurality of pattern portions PP may be defined as a ratio of the number of the plurality of pattern portions PP in a randomly selected region of the adhesive layer 10 to an area (or “unit area”) of the randomly selected region of the adhesive layer 10.

For example, a first ratio of the number of the plurality of pattern portions PP to the area of the adhesive layer 10 in a first region R1 may be the same as a second ratio of the number of the plurality of pattern portions PP to the area of the adhesive layer 10 in a second region R2.

Also, the second ratio may be the same as a third ratio of the number of the plurality of pattern portions PP to the area of the adhesive layer 10 in a third region R3. Here, the first to third regions R1, R2, and R3 may be randomly selected regions in the adhesive layer 10.

From a second perspective, the configuration in which the plurality of pattern portions PP may be regularly arranged on the adhesive layer 10 may indicate that the shape and the size of the incision portion IP may be substantially the same throughout the entire region of the adhesive layer 10. The incision portion IP may have an open square shape having substantially the same size in the first to third regions R1, R2, and R3, for example. From another perspective, the first and second lengths L1 and L2 of the pattern portion PP in the first region R1 may be substantially the same as the first and second lengths L1 and L2 of the pattern portion PP in the second region R2, respectively.

FIGS. 3B and 3C are enlarged diagrams illustrating a portion of an adhesive tape sheet according to an example embodiment, illustrating region “A” in FIG. 2.

Referring to FIG. 3B, an adhesive layer 10a may be the same as or similar to the example described with reference to FIG. 1 to FIG. 3A, other than the configuration in which the adhesive layer 10a includes at least one pattern portion PP in which a length L1 in the horizontal direction of the open portion OP is greater than the length L2 in the vertical direction of the extension portion EP.

From another perspective, the length in the horizontal direction of the incision portion IP may be greater than the length in the vertical direction.

Referring to FIG. 3C, an adhesive layer 10b may be the same as or similar to the example described with reference to FIG. 1 to FIG. 3B, other than the configuration in which the adhesive layer 10B includes at least one pattern portion PP in which the length L2 in the vertical direction of the extension portion EP is greater than the length L1 in the horizontal direction of the open portion OP.

From another perspective, the length in the vertical direction of the incision portion IP may be greater than the length in the horizontal direction.

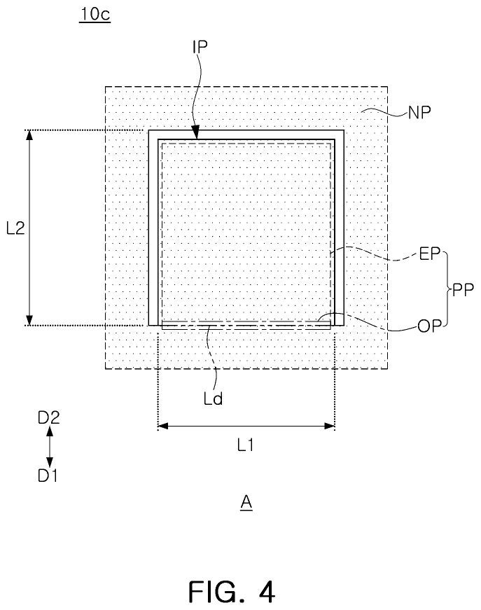

FIG. 4 is an enlarged diagram illustrating an adhesive tape sheet according to an example embodiment, illustrating region “A” in FIG. 2.

Referring to FIG. 4, the example may be the same as or similar to the example described with reference to FIG. 1 to FIG. 3C other than the configuration in which the incision portion IP formed on the adhesive layer 10c has a thickness.

The incision portion IP may be formed to have a thickness along the first to third sides s1, s2, and s3 of the extension portion EP. The incision portion IP may extend with a substantially uniform thickness along the first to third sides s1, s2, and s3. The thickness of the incision portion IP may be less than the length L1 of the open portion OP and/or the length L2 of the extension portion EP.

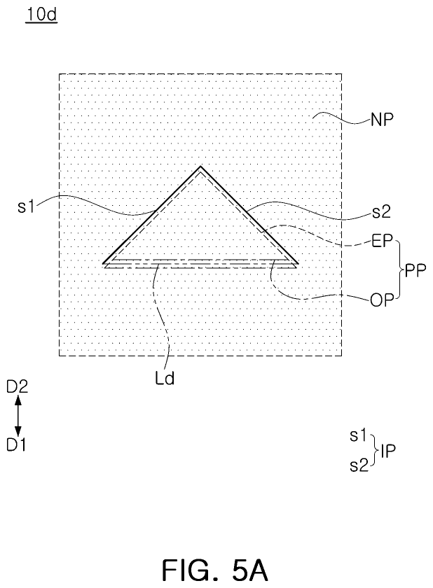

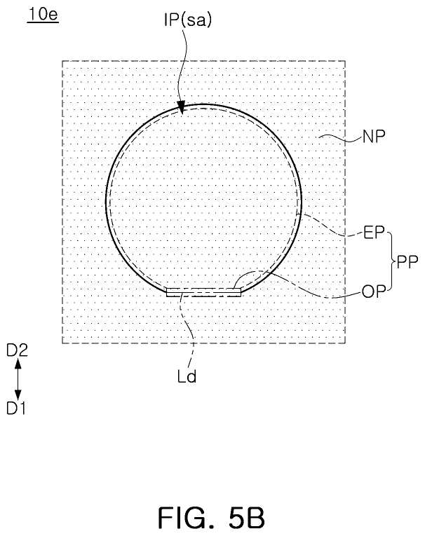

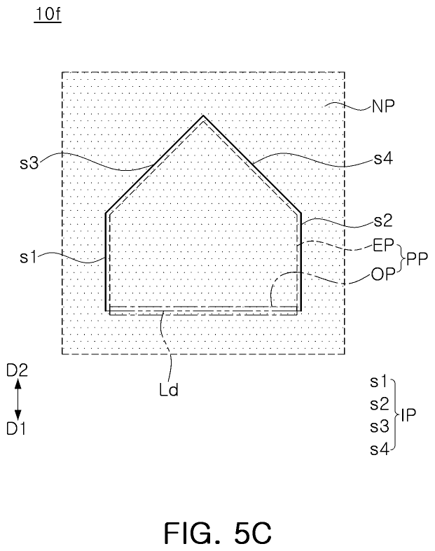

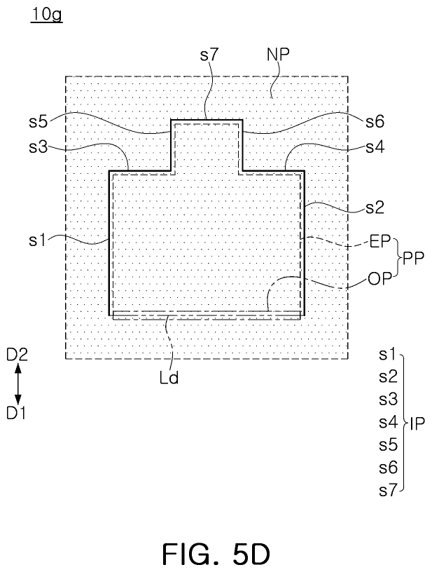

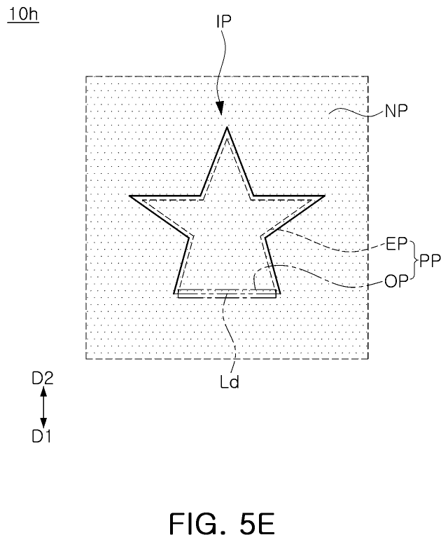

FIGS. 5A to 5E are enlarged diagrams illustrating a portion of an adhesive tape sheet according to an example embodiment, illustrating region “A” in FIG. 2.

Referring to FIG. 5A, the adhesive layer 10d may be the same as or similar to the example described with reference to FIGS. 1 to 4, other than the configuration in which the incision portion IP has an open triangular shape.

By the incision portion IP, the extension portion EP may include a first side s1 and a second side s2 extending diagonally from both ends of the open portion OP, respectively, and meeting each other. From another perspective, the incision portion IP may have two sides formed along the first and second sides s1 and s2 of the extension portion EP and three corners corresponding to the corners of the extension portion EP.

Referring to FIG. 5B, the adhesive layer 10e may be the same as or similar to the example described with reference to FIGS. 1 to 5A, other than the configuration in which the incision portion IP has an open circular shape.

By the incision portion IP, the extension portion EP may have a side surface sa extending from both ends of the open portion OP and having an arc shape. From another perspective, the incision portion IP may have a side surface formed along the side surface sa of the extension portion EP and having an arc shape.

Referring to FIG. 5C, the adhesive layer 10f may be the same as or similar to the example described with reference to FIGS. 1 to 5B, other than the configuration in which the incision portion IP has an open spiral (e.g., open irregular pentagon) shape.

By the incision portion IP, the extension portion EP may include a first side s1 and a second side s2 extending from both ends of the open portion OP in the second direction D2, respectively, and opposing each other. The extension portion EP may further include a third side and a fourth side s3 and s4 extending diagonally from the ends of the first and second sides s1 and s2, respectively, and meeting each other on the open portion OP. From another perspective, the incision portion IP may be formed along the first to fourth sides s1, s2, s3, and s4 of the extension portion EP and may have a spiral shape having open one side.

Referring to FIG. 5D, the adhesive layer 10g may be the same as or similar to the example described with reference to FIGS. 1 to 5C, other than the configuration in which the incision portion IP formed on the adhesive layer 10g has an open square shape having a protrusion on an upper side.

By the incision portion IP, the extension portion EP may include a first side s1 and a second side s2 extending from both ends of the open portion OP in the second direction D2 and opposing each other.

The extension portion EP may further include a third side and a fourth side s3 and s4 extending in the horizontal direction from ends of the first and second sides s1 and s2, respectively.

The extension portion EP may further include fifth and sixth sides s5 and s6 extending in a second direction D2 from the ends of the third and fourth sides s3 and s4, respectively, and faces each other.

The extension portion EP may further include a seventh side s7 extending in a horizontal direction from ends of the fifth and sixth sides s5 and s6 and meeting each other on the open portion OP.

From another perspective, the incision portion IP may have a shape of an open square shape having a protrusion on the upper portion.

Referring to FIG. 5E, the adhesive layer 10h may be the same as or similar to the example described with reference to FIGS. 1 to 5D, other than the configuration in which the incision portion IP has an open star shape.

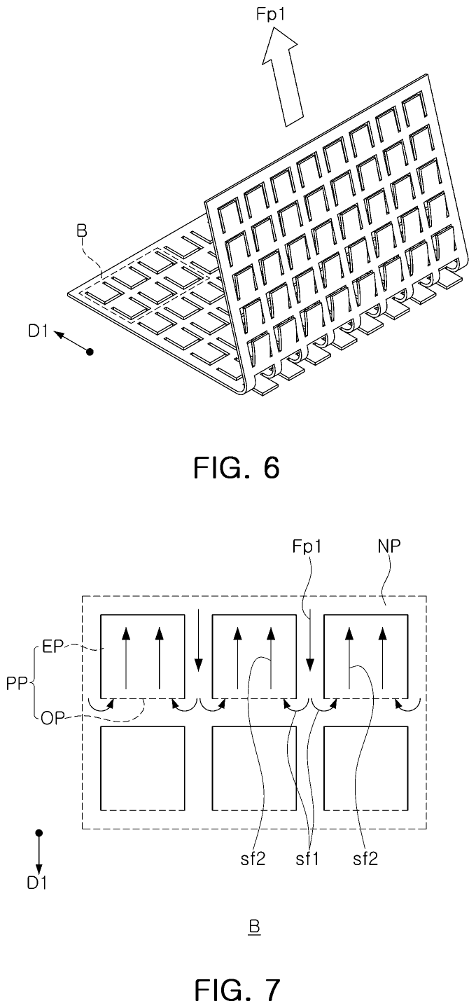

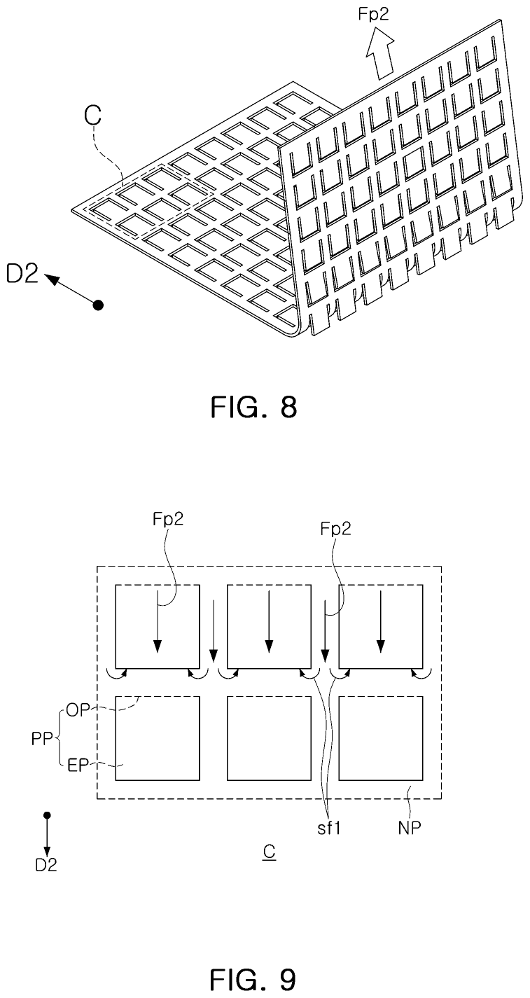

FIGS. 6 and 8 are perspective diagrams illustrating the example in which an adhesive tape sheet 1 (or “adhesive layer 10”) is peeled in different directions. FIG. 7 is an enlarged diagram illustrating a portion of region “B” in FIG. 6, and FIG. 9 is an enlarged diagram illustrating a portion of region “C” in FIG. 8.

In the description with reference to FIGS. 6 to 9, the terms “peel” and “peeling force” may be used. The peel may indicate removing the tape sheet 1 (or “adhesive layer 10”) from the adherend, and the peeling force may be defined as force for peeling the adhesive tape sheet 1 from the adherend. The adherend (not illustrated) may be attached to a lower portion of the adhesive layer 10.

In the description with reference to FIGS. 6 and 7, the force applied to the adhesive layer 10 to peel the adhesive layer 10 from the adherend in the first direction D1 may be referred to as a first peeling force Fp1.

In the description with reference to FIGS. 8 and 9, the force applied to the adhesive layer 10 to peel the adhesive layer 10 from the adherend in the second direction D2 may be referred to as a second peeling force Fp2.

FIG. 6 is a perspective diagram illustrating the example in which the adhesive layer 10 is peeled in the first direction D1. FIG. 7 is an enlarged diagram illustrating a portion of region “B” in FIG. 6, illustrating the relationship between the forces applied to the adhesive layer 10.

Referring to FIGS. 6 and 7, the peeling force Fp1 in the first direction D1 may be applied to the adhesive layer 10. The first direction D1 may be a direction in which the open portion OP of the pattern portion PP is connected to the non-patterned portion NP, and may be a direction opposite to the second direction D2 in which the extension portion EP of the pattern portion PP extends (see FIGS. 2 to 3C).

When the peeling force Fp1 is applied along the non-patterned portion NP in the first direction D1, a first stress sf1 and a second stress sf2 may occur for the peeling force Fp1.

The first stress sf1 may act on a boundary between the pattern portion PP and the non-patterned portion NP, for example, on both ends of the open portion OP. The first stress sf1 may include a plurality of stresses having different vectors with respect to each of the both ends of the open portion OP. Each vector of the plurality of stresses may include a direction intersecting the first direction D1.

The second stress sf2 may act on the pattern portion PP, for example, on the extension portion EP. At least a portion of the second stress sf2 may be due to adhesion between the adherend and adhesive layer 10. The second stress sf2 may have a vector in the second direction D2 opposite to the first direction D1 in which the peeling force Fp1 is applied.

In an example embodiment, peeling resistance due to the first stress sf1 and the second stress sf2 may be maximum. Accordingly, the peeling force Fp1 may have a maximum value among a plurality of peeling forces for peeling the adhesive layer 10.

FIG. 8 is a perspective diagram illustrating the example in which the adhesive layer 10 is peeled in the second direction D2. FIG. 9 is a portion enlarged diagram illustrating region “C” in FIG. 8, illustrating the relationship between forces applied to the adhesive layer 10.

Referring to FIGS. 8 and 9, the peeling force Fp2 in the second direction D2 may be applied to the adhesive layer 10. The second direction D2 may be the direction in which the extension portion EP of the pattern portion PP extends, and may opposite to the first direction D1 in which the open portion OP of the pattern portion PP is connected to the non-patterned portion NP (see FIGS. 2 to 3C).

When the peeling force Fp2 is applied along the non-patterned portion NP in the second direction D2, a first stress sf1 for the peeling force Fp2 may occur.

The first stress sf1 may act on a boundary between the pattern portion PP and the non-patterned portion NP, for example, on both ends of the open portion OP. The first stress sf1 may include a plurality of stresses having different vectors with respect to each of the both ends of the open portion OP. Each vector of the plurality of stresses may include a direction intersecting the second direction D2. The first stress sf1 described with reference to FIG. 8 may be smaller than the first stress sf1 described with reference to FIG. 6.

Differently from described with reference to FIG. 6, in the example embodiment, the stress acting in the first direction D1 opposite to the second direction D2 in which the peeling force Fp2 is applied may not be present. This may be because the direction in which the peeling force Fp2 is applied and the direction in which the extension portion EP of the pattern portion PP extends may be substantially the same in the second direction D2. Accordingly, the second peeling force Fp2 may have a minimum value among a plurality of peeling forces for peeling the adhesive layer 10.

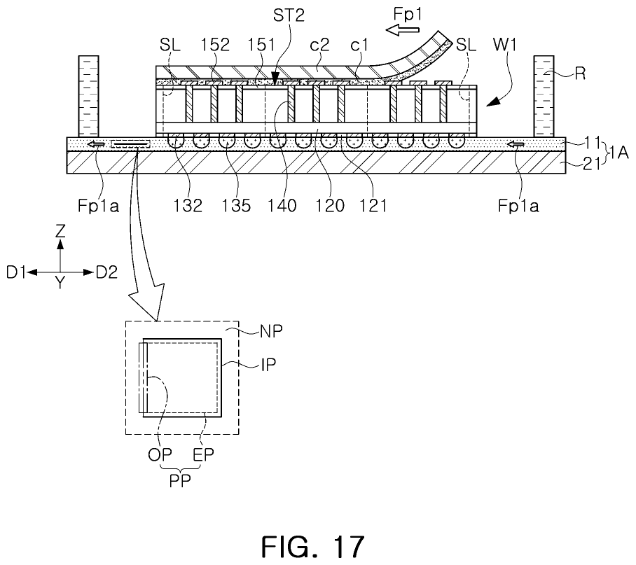

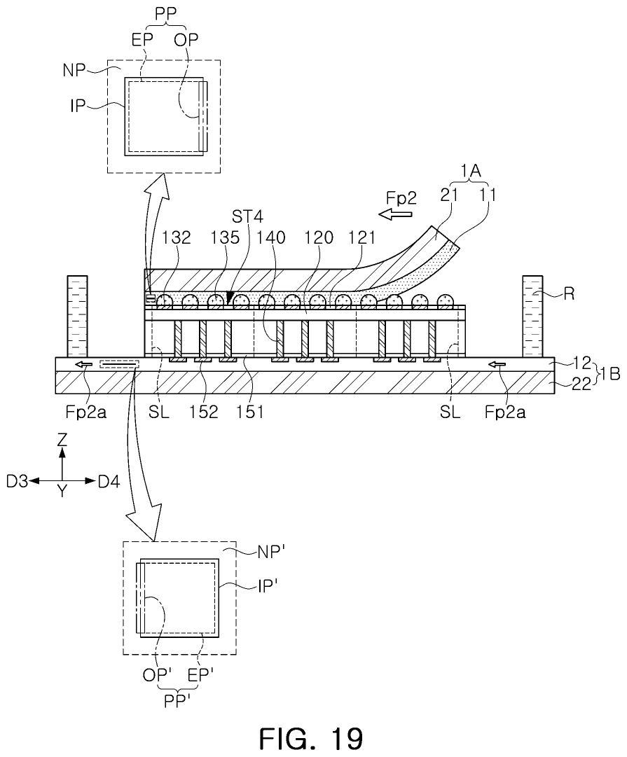

The peeling forces Fp1 and Fp2 described with reference to FIG. 6 to FIG. 9 may be due to external forces directly physically applied to the adhesive layer 10, but an example embodiment thereof is not limited thereto. The external force may be, for example, an indirect force transferred to the adhesive layer 10 from a peeling force applied to a film attached to the other surface of the adherend, which will be described with reference to FIGS. 17 and 19.

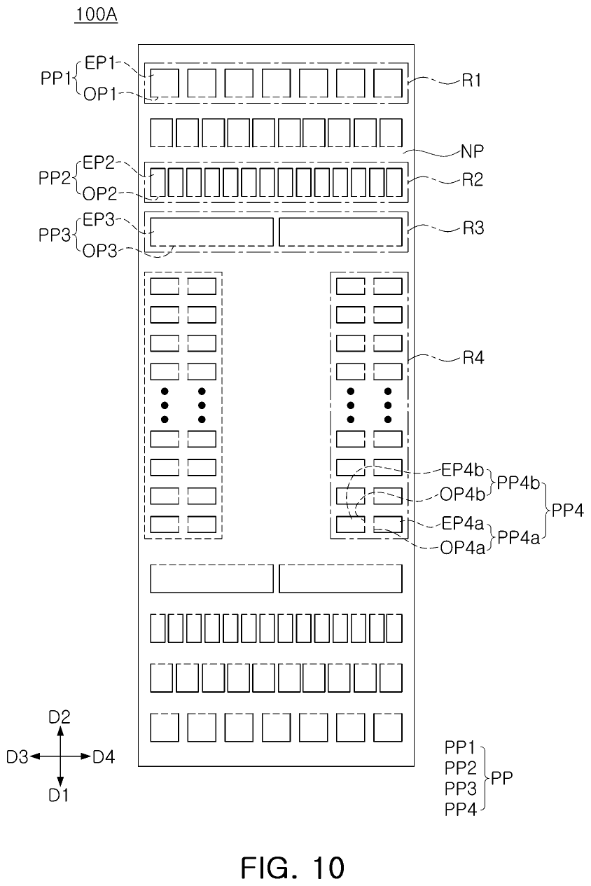

FIG. 10 is an enlarged diagram illustrating a portion of an adhesive tape sheet according to an example embodiment.

Referring to FIG. 10, the example may be the same as or similar to the example described with reference to FIG. 1 to FIG. 9 other than the configuration in which the plurality of pattern portions PP are partially regularly arranged on the adhesive layer 100A.

From a first perspective, the configuration in which the plurality of pattern portions PP are partially regularly arranged may indicate that the densities of the plurality of pattern portions PP may be different depending on the regions of the adhesive layer 100A.

The densities of the plurality of pattern portions PP may be defined as a ratio of the number of the plurality of pattern portions PP to an area (or “unit area”) of a region of the adhesive layer 100A.

The adhesive layer 100A may be defined as a plurality of first to fourth regions R1, R2, R3, and R4 according to the ratio of the number of the plurality of pattern portions PP to the area of the adhesive layer 100A.

In each of the plurality of first to fourth regions R1, R2, R3, and R4, the ratio of the number of the plurality of pattern portions PP1, PP2, PP3, and PP4 to the area of the adhesive layer 100A may be constant. For example, in the first region R1, the first ratio of the number of the plurality of pattern portions PP1 to the area of the adhesive layer 100A may be constant. In the second region R2, the second ratio of the number of the plurality of pattern portions PP2 to the area of the adhesive layer 100A may be constant. In the third region R3, the third ratio of the number of the plurality of pattern portions PP3 to the area of the adhesive layer 100A may be constant. In the fourth region R4, the fourth ratio of the number of the plurality of pattern portions PP4 to the area of the adhesive layer 100A may be constant.

The ratios of the number of each of the plurality of pattern portions PP1, PP2, PP3, and PP4 to the area of the adhesive layer 100A in the plurality of first to fourth regions R1, R2, and R3, R4 may be different. For example, the first to fourth ratios may be different.

From a second perspective, the configuration in which the plurality of pattern portions PP are partially regularly arranged may indicate that the arrangements of the plurality of pattern portions PP are different depending on the regions of the adhesive layer 100A.

The arrangement of the plurality of pattern portions PP may be determined with respect to the direction in which the open portion OP is connected to the non-patterned portion NP and/or the direction in which the extension portion EP extends from the open portion OP.

For example, in the first to third regions R1, R2, and R3, the plurality of pattern portions PP1, PP2, and PP3 may be disposed such that the direction in which each of the open portions OP1, OP2, and OP3 is connected to the non-patterned portion NP may be a first direction D1, and the direction in which the extension portions EP1, EP2, and EP3 extend from the open portions OP1, OP2, and OP3 may be a second direction D2 opposite to the first direction D1.

In the fourth region R4, the direction in which the open portion OP4a of the pattern portions PP4a disposed on one side (e.g., a first side) is connected to the non-patterned portion NP may be a third direction D3, and the direction in which the extension portion EP4a extends from the open portion OP4a may be a fourth direction D4 opposite to the third direction D3. Here, the third and fourth directions D3 and D4 may be directions perpendicular to the first and second directions D1 and D2 on the same plane. Also, in the fourth region R4, the direction in which the open portion OP4b of the pattern portions PP4b disposed on another side opposite to the one side (e.g., a second side) is connected to the non-patterned portion NP may be the fourth direction D4, and the direction in which the extension portion EP4b extends from the open portion OP4b may be the third direction D3.

For example, in the fourth region R4, a plurality of pattern portions PP4 may be disposed such that the open portion OPa of the pattern portions PP4a disposed on the one side (e.g., the first side) and the open portion OP4b of the pattern portions PP4b disposed on the other side (e.g., the second side) may oppose each other. Accordingly, when a peeling force is applied in the first direction D1 or the second direction D2, stresses occurring in the open portions OPa and OPb of the pattern portions PP4 of the fourth region R4 may be offset from each other. The fourth region R4 may be referred to as an offset region.

In each region of the adhesive layer 100A, the densities of the plurality of pattern portions PP or configuring the arrangement of the plurality of pattern portions PP differently may be determined depending on the adherend.

In an example embodiment, the configuration (for example, the configuration of the pattern portion PP) may be determined by the density of the pattern formed on one surface of the adherend. For example, the density of the pattern portions PP of the adhesive layer 100A corresponding to a region in which the density of the pattern of the adherend is relatively great may be configured to be greater than the density of the pattern portions PP of the adhesive layer 100A corresponding to a region in which the density of the pattern of the adherend is relatively small. The pattern (for example, the pattern of the adherend) may include a semiconductor pattern disposed according to a connection pad and a connection bump formed on the one surface of the adherend.

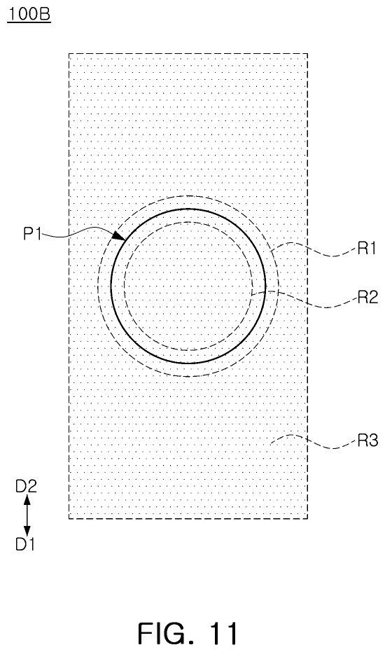

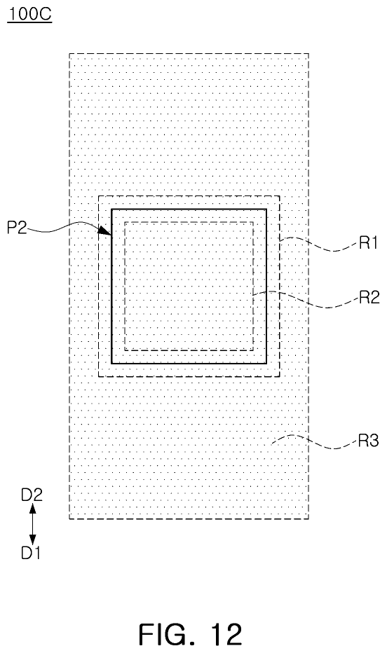

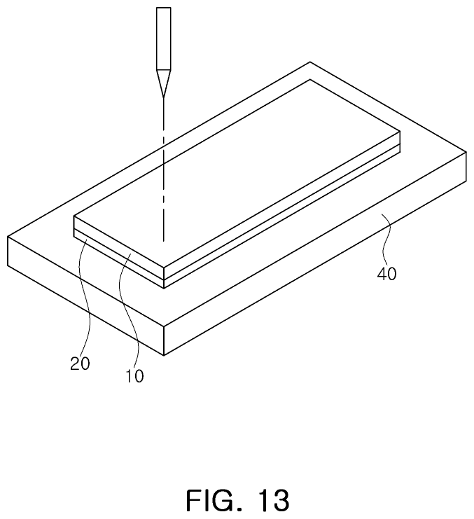

FIGS. 11 and 12 are enlarged diagrams illustrating a portion of an adhesive tape sheet according to an example embodiment.

Referring to FIGS. 11 and 12, adhesive layers 100B and 100C may be the same as or similar to the examples described with reference to FIGS. 1 to 10, other than the configuration in which the pattern portions PP are densely arranged along the edge of the region to which the adherends P1 and P2 are attached.

Referring to FIG. 11, a circular adherend P1 may be attached on the adhesive layer 100B. In the example embodiment, the adherend P1 may be a semiconductor wafer (W1 in FIG. 16).

The adhesive layer 100B may be defined to have first to third regions R1, R2, and R3. The second region R2 may be defined as a region completely overlapping the adherend P1 vertically. For example, in a plan view, the edge (e.g., boundary) of the second region R2 may not extend beyond the edge of the adherend P1. In another example, in a plan view, the edge of the second region R2 may be completely within the edge of the adherend P1. The first region R1 may be defined as a region formed along the edge of the adherend P1 surrounding the second region R2. For example, in a plan view, the first region R1 may have an annular shape, but not limited thereto. For example, in a plan view, a first portion of the first region R1 may be formed within the edge of the adherend P1 and a second portion of the first region R1 may extend beyond the edge of the adherend P1. The third region R3 may be defined as a region surrounding the first region R1 and not overlapping the adherend P1 in a plan view.

The density of the pattern portions PP of adhesive layer 100B in the first region R1 may be greater than the density of the pattern portions PP of adhesive layer 100B in the second region R2 and/or the density of the pattern portions PP of the adhesive layer 100B in the third region R3.

The second region R2 may include a plurality of local regions, and the density of the pattern portions PP of the adhesive layer 100B may be varied depending on the plurality of local regions. In the plurality of local regions, the density of the pattern portions PP of the adhesive layer 100B may be determined by the density of patterns formed on one surface of the adherend P1. The pattern may include a semiconductor pattern disposed according to a connection pad and a connection bump formed on the one surface of the adherend P1.

Referring to FIG. 12, an adherend P2 having a square shape may be attached on the adhesive layer 100C. In the example embodiment, the adherend P2 may be a semiconductor chip.

The adhesive layer 100C may be defined to have first to third regions R1, R2, and R3. The second region R2 may be defined as a region completely overlapping the adherend P2 vertically. For example, in a plan view, the edge (e.g., boundary) of the second region R2 may not extend beyond the edge of the adherend P2. In another example, in a plan view, the edge of the second region R2 may be completely within the edge of the adherend P2. The first region R1 may be defined as a region surrounding the second region R2 and formed along an edge of the adherend P2. For example, in a plan view, a first portion of the first region R1 may be formed within the edge of the adherend P2 and a second portion of the first region R1 may extend beyond the edge of the adherend P2. The third region R3 may be defined as a region surrounding the first region R1 and not overlapping the adherend P2 in a plan view.

As described with reference to FIG. 11, the density of the pattern portions PP of the adhesive layer 100C in the first region R1 may be greater than the density of the pattern portions PP of the adhesive layer 100C in the second region R2 and/or the density of the pattern portions PP of the adhesive layer 100C in the third region R3.

The second region R2 may include a plurality of local regions, and the density of the pattern portions PP of the adhesive layer 100C may be varied depending on the plurality of local regions. In the plurality of local regions, the density of the pattern portions PP of the adhesive layer 100C may be determined by the density of patterns formed on one surface of the adherend P2. The pattern may include a semiconductor pattern disposed according to a connection pad and a connection bump formed on the one surface of the adherend P2.

FIG. 13 is a perspective diagram illustrating a method of manufacturing an adhesive tape sheet according to an example embodiment.

Referring to FIG. 13, a substrate layer 20 and an adhesive layer 10 may be provided on a substrate 40.

The substrate 40 may be provided to perform a laser-based subtraction manufacturing technique to form adhesion patterns (“PP” in FIG. 2) on one surface of the adhesive layer 10, and may fix and support the substrate layer 20 and the adhesive layer 10.

Using the laser-based subtraction manufacturing technique, various designs of adhesion patterns may be applied to the one surface of the adhesive layer 10. For example, depending on the purpose of use of the adhesive tape sheet, adhesion patterns (“PP” in FIG. 3B, FIG. 3C, FIG. 4, and FIG. 5A to FIG. 5E) of various shapes may be formed, or the density of the adhesion patterns may be designed differently for each region of the adhesive layers (“100A” in FIG. 10, “100B” in FIGS. 11, and “100C” in FIG. 12).

Thereafter, a cover layer (“30” in FIG. 1) may be provided on the adhesive layer 10, such that the adhesive tape sheet 1 may be provided.

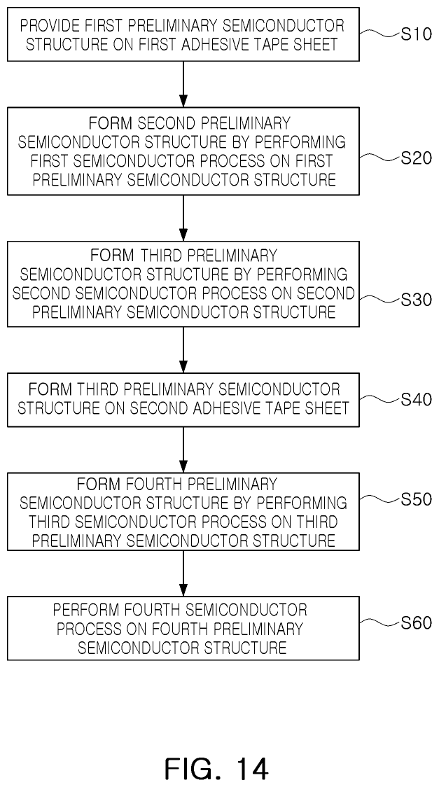

FIG. 14 is a flowchart illustrating ordered processes of a method of manufacturing a semiconductor device using an adhesive tape sheet according to an example embodiment.

Referring to FIG. 14, manufacturing a semiconductor device using adhesive tape sheet 1 may include providing a first preliminary semiconductor structure on the adhesive tape sheet, and performing a plurality of semiconductor processes on the first preliminary semiconductor structure.

In an example embodiment, the first preliminary semiconductor structure may include a semiconductor wafer, and the semiconductor device may include individualized semiconductor chips cut out from the semiconductor wafer.

The manufacturing a semiconductor device using the adhesive tape sheet 1 may include providing a first preliminary semiconductor structure on a first adhesive tape sheet (S10), forming a second preliminary semiconductor structure (S20) by performing a first semiconductor process on the first preliminary semiconductor structure, forming a third preliminary semiconductor structure by performing a second semiconductor process on the second preliminary semiconductor structure (S30), providing a third preliminary semiconductor structure on the second adhesive tape sheet (S40), performing a third semiconductor process on the third preliminary semiconductor structure to form a fourth preliminary semiconductor structure (S50), and performing a fourth semiconductor process on the fourth preliminary semiconductor structure (S60).

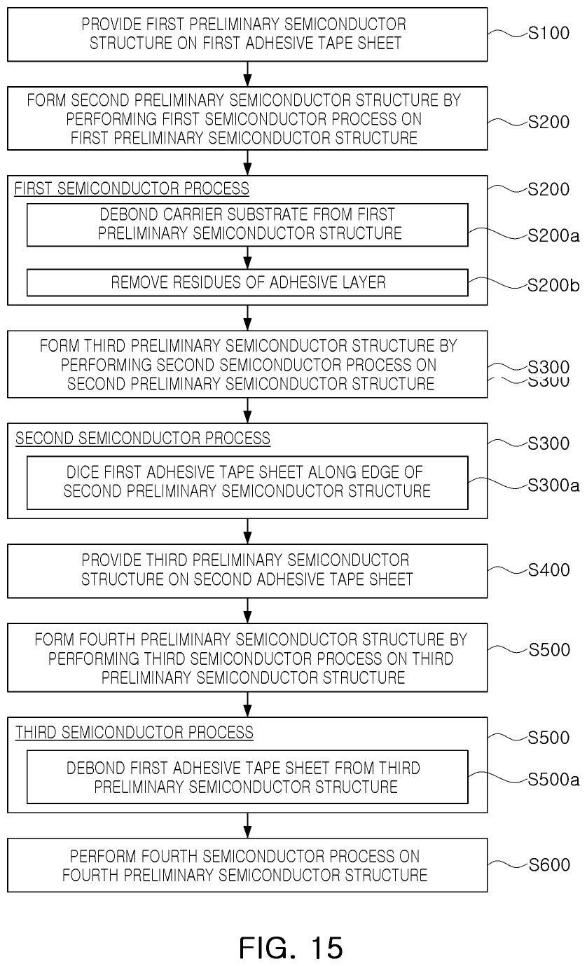

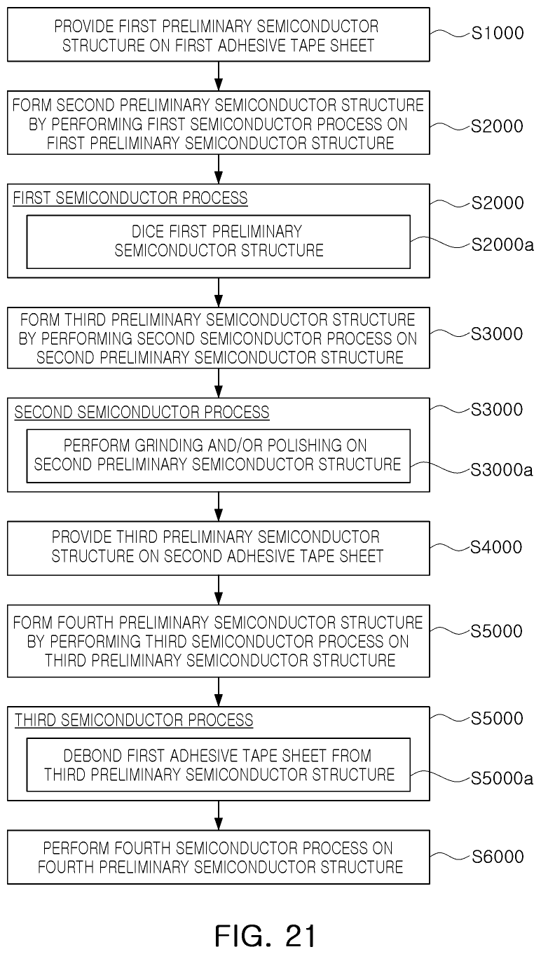

In example embodiments, the first, second, and third semiconductor processes may be performed differently (see FIGS. 15 and 21).

FIG. 15 is a flowchart illustrating ordered processes of a method of manufacturing a semiconductor device using an adhesive tape sheet according to an example embodiment.

FIGS. 16 to 20 are vertical cross-sectional diagrams illustrating a method of manufacturing a semiconductor device using an adhesive tape sheet according to an example embodiment, process diagrams based on the flowchart in FIG. 15.

Referring to FIGS. 15 and 16, a first preliminary semiconductor structure ST1 may be provided on a first adhesive tape sheet 1A S100.

A first adhesive tape sheet 1A including a substrate layer 21 and an adhesive layer 11 may be provided. The substrate layer 21 and the adhesive layer 11 may be components corresponding to the substrate layer 20 and the adhesive layer 10 described with reference to FIGS. 1 to 3A. Additionally, the adhesive layer 11 of the first adhesive tape sheet 1A may include configurations the same as or similar to the example configurations described with reference to FIGS. 3B, 3C, 4, and 5A-5E. The adhesive layer 11 of the first adhesive tape sheet 1A may also include a plurality of pattern portions PP that are partially regularly arranged as described with reference to FIG. 10.

The adhesive layer 11 may include a plurality of pattern portions PP defined by a non-patterned portion NP and an incision portion IP. An open portion OP of the plurality of pattern portions PP may be formed to be connected to the non-patterned portion NP in a first direction D1. An extension portion EP of the plurality of pattern portions PP may be formed to extend in a second direction D2 opposite to the first direction D1.

A ring frame R may be provided on the first adhesive tape sheet 1A. The ring frame R may be a component for dicing a first preliminary semiconductor structure ST1 on the first adhesive tape sheet 1A.

A first preliminary semiconductor structure ST1 may be provided on the first adhesive tape sheet 1A. The first preliminary semiconductor structure ST1 may include a semiconductor wafer W1 as an adherend attached to an upper surface of the first adhesive tape sheet 1A.

The semiconductor wafer W1 may include a circuit layer 120 formed on a front surface, a front surface insulating layer 121, front connection pads 132, connection bumps 135, through-electrodes 140 disposed within chip regions separated by scribe lane SL, and a backside insulating layer 151 and backside connection pads 152 formed on a back surface.

The first preliminary semiconductor structure ST1 may further include an adhesive layer c1 and a carrier substrate c2 formed on a back surface of a semiconductor wafer W1. The semiconductor wafer W1 may be provided on a first adhesive tape sheet 1A by the carrier substrate c2. The carrier substrate c2 may be a component for supporting and handling the semiconductor wafer W1. The semiconductor wafer W1 may be temporarily fixed and supported on the carrier substrate c2 by the adhesive layer c1. The adhesive layer c1 may cover backside connection pads 152 on the backside insulating layer 151.

In an example embodiment, the semiconductor wafer W1 may be provided to not include a front surface insulating layer 121 and connection bumps 135. In this case, the adhesive layer 11 may cover front connection pads 132.

The first adhesive tape sheet 1A may be defined to have a second region R2 to which a first preliminary semiconductor structure ST1 is attached and which completely vertically overlaps a front surface of the first preliminary semiconductor structure ST1, a first region R1 formed along an edge of the first preliminary semiconductor structure ST1 and surrounding the second region R2, and a third region R3 to which the first preliminary semiconductor structure ST1 is not attached and which surrounds the first region R1. Also, the first adhesive tape sheet 1A may be defined to have an attachment region RR to which a ring frame R is attached.

The densities of the plurality of pattern portions of the adhesive layer 11 in the regions R1, R2, and R3 may be different. For example, the densities of the plurality of pattern portions of the adhesive layer 11 in the first region R1 and second region R2 may be greater than the densities of the plurality of pattern portions of the adhesive layer 11 in the third region R3. The densities of the plurality of pattern portions of the adhesive layer 11 in the second region R2 may be different depending on the pattern densities of the front connection pads 132 and/or the connection bumps 135 formed on the front surface of the semiconductor wafer W1. For example, the densities of the plurality of pattern portions in the region overlapping the scribe lane SL in the second region R2 may be less than the density in the other region in the second region R2.

Referring to FIG. 15 and FIG. 17, a first semiconductor process may be performed on the first preliminary semiconductor structure ST1 and a second preliminary semiconductor structure ST2 may be formed (S200).

The first semiconductor process may include debonding a carrier substrate c2 from the first preliminary semiconductor structure ST1 (S200a).

Debonding the carrier substrate c2 (S200a) may include peeling the carrier substrate c2 in the first direction D1 by applying a peeling force Fp1 in the first direction D1 to the carrier substrate c2. A portion Fp1a of the peeling force Fp1 may be transferred to the adhesive layer 11 of the first adhesive tape sheet 1A, and the portion Fp1a of the peeling force Fp1 may be applied in the first direction D1 to the adhesive layer 11 of the first adhesive tape sheet 1A. Accordingly, in the debonding process, the adhesive layer 11 of the first adhesive tape sheet 1A may have a strong adhesive force with respect to the first preliminary semiconductor structure ST1. Accordingly, cracks occurring on an edge of the first preliminary semiconductor structure ST1 may be reduced by the debonding process, and residues of the adhesive layer c1 on a back surface of the semiconductor wafer W1 may be reduced.

The first semiconductor process may further include removing residues of the adhesive layer c1 remaining on the back surface of the semiconductor wafer W1 (S200b). The adhesive layer c1 may be removed using a solvent. The adhesive layer 11 of the first adhesive tape sheet 1A may have strong chemical resistance against the solvent by including a material described with reference to FIG. 1, such that chemical wear of the adhesive layer 11 may be reduced.

The second preliminary semiconductor structure ST2 may indicate a semiconductor wafer W1 from which the adhesive layer c1 and a carrier substrate c2 are removed.

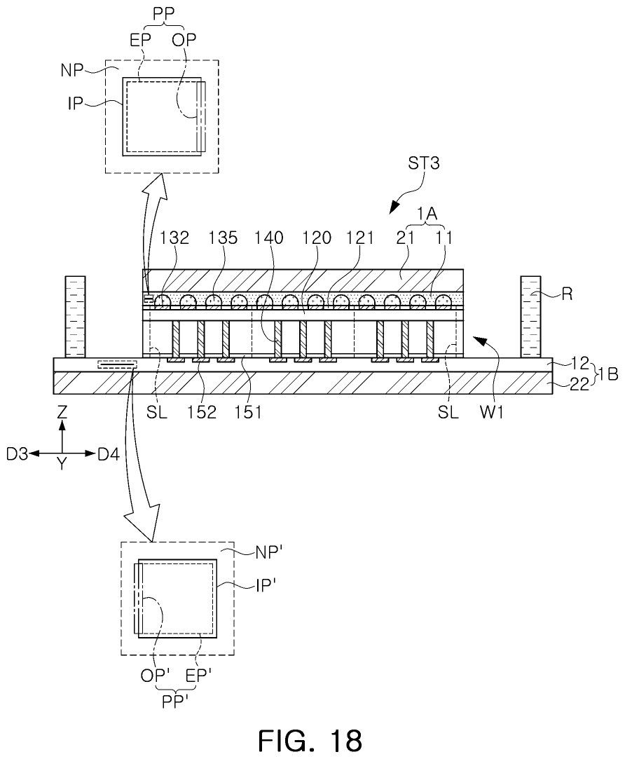

Referring to FIGS. 15 and 18, a third preliminary semiconductor structure ST3 may be formed by performing a second semiconductor process on the second preliminary semiconductor structure ST2 (S300). Thereafter, the third preliminary semiconductor structure ST3 may be provided on a second adhesive tape sheet 1B (S400).

The second semiconductor process may include dicing the first adhesive tape sheet 1A along an edge of the second preliminary semiconductor structure ST2 (S300a).

According to example embodiments, before the second semiconductor process is performed, UV curing treatment for the adhesive layer 11 may be unnecessary.

The third preliminary semiconductor structure ST3 may refer to the semiconductor wafer W1 and the diced first adhesive tape sheet 1A.

Providing the third preliminary semiconductor structure ST3 (S400) may include flipping the third preliminary semiconductor structure ST3 and providing the structure on the second adhesive tape sheet 1B.

The second adhesive tape sheet 1B may include a substrate layer 22 and an adhesive layer 12. The substrate layer 22 and the adhesive layer 12 may be components corresponding to the substrate layer 20 and the adhesive layer 10 described with reference to FIGS. 1 to 3A. Additionally, the adhesive layer 12 of the second adhesive tape sheet 1B may include configurations the same as or similar to the example configurations described with reference to FIGS. 3B, 3C, 4, and 5A-5E. The adhesive layer 12 of the second adhesive tape sheet 1B may also include a plurality of pattern portions PP that are partially regularly arranged as described with reference to FIG. 10.

The adhesive layer 12 may include a plurality of pattern portions PP′ defined by a non-patterned portion NP′ and an incision portion IP′. The open portion OP′ of the plurality of pattern portions PP′ may be formed to be connected to the non-patterned portion NP′ in the third direction D3. The extension portion EP′ of the plurality of pattern portions PP′ may be formed to extend in the fourth direction D4 opposite to the third direction D3.

Providing the third preliminary semiconductor structure ST3 (S400) may include providing the structure in a first direction (“D1” of FIGS. 16 and 17) in which the open portion OP of the plurality of pattern portions PP of the adhesive layer 11 is connected to the non-patterned portion NP may be directed in the direction opposite to the third direction D3. From another perspective, the third preliminary semiconductor structure ST3 may be provided such that the second direction (“D2” of FIGS. 16 and 17) in which the extension portion EP of the adhesive layer 11 extends may be directed in the direction opposite to the fourth direction D4.

Referring to FIGS. 15 and 19, the fourth preliminary semiconductor structure ST4 may be formed by performing a third semiconductor process on the third preliminary semiconductor structure ST3 (S500).

The third semiconductor process may include debonding the first adhesive tape sheet 1A from the third preliminary semiconductor structure ST3 (S500a).

Debonding the first adhesive tape sheet 1A (S500a) may include peeling the first adhesive tape sheet 1A in the third direction D3 by applying a peeling force Fp2 to the first adhesive tape sheet 1A in the third direction D3. A portion Fp2a of the peeling force Fp2 may be transferred to the adhesive layer 12, and the portion Fp2a of the peeling force Fp2 may be applied to the adhesive layer 12 in the third direction D3. Accordingly, in the debonding process, the adhesive layer 12 may have a strong adhesive force to the third preliminary semiconductor structure ST3. Accordingly, cracks occurring at the edge of the third preliminary semiconductor structure ST3 may be reduced by the debonding process. The first adhesive tape sheet 1A may be peeled relatively easily. The peeled first adhesive tape sheet 1A may be reused after cleaning.

The fourth preliminary semiconductor structure ST4 may indicate the semiconductor wafer W1 from which the first adhesive tape sheet 1A is removed.

Referring to FIG. 15 and FIG. 20, a fourth semiconductor process may be performed on the fourth preliminary semiconductor structure ST4 (S600).

The fourth semiconductor process may include individualizing the fourth preliminary semiconductor structure ST4 into a plurality of semiconductor chips C along the scribe lane SL using a blade wheel BW. In this case, the second adhesive tape sheet 1B may also be cut into a plurality of components.

Thereafter, each of the individualized plurality of semiconductor chips C may be attached to an adhesive tape sheet according to an example embodiment and a subsequent semiconductor packaging process may be performed thereon. In the subsequent semiconductor packaging process, the attaching each of the plurality of semiconductor chips C to the adhesive tape sheet and the removing the adhesive tape sheet from each of the plurality of semiconductor chips C may be substantially the same as in the example described with reference to FIGS. 16 to 20.

FIG. 21 is a flowchart illustrating processes of a method of manufacturing a semiconductor device using an adhesive tape sheet in order according to an example embodiment.

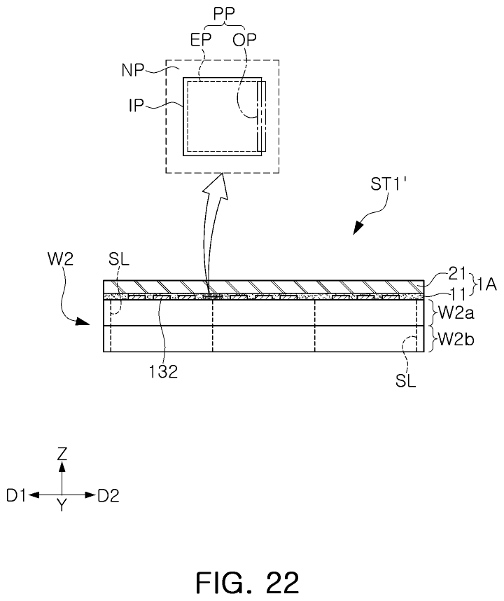

FIGS. 22 to 26 are vertical cross-sectional diagrams illustrating a method of manufacturing a semiconductor device using an adhesive tape sheet according to an example embodiment, process diagrams based on the flowchart in FIG. 21.

Referring to FIGS. 21 and 22, a first preliminary semiconductor structure ST1′ may be provided on a first adhesive tape sheet 1A (S1000).

The first preliminary semiconductor structure ST1′ may be an adherend attached to an adhesive layer 11 of the first adhesive tape sheet 1A, and may include a semiconductor wafer W2.

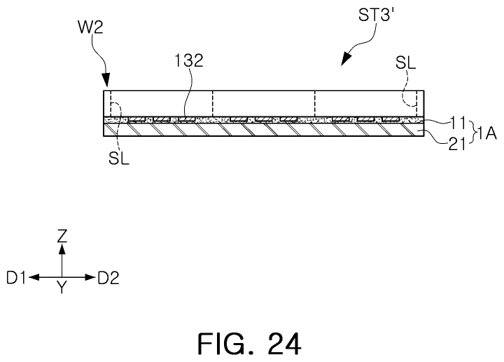

The semiconductor wafer W2 may include a region W2a in which through-electrodes (not illustrated) disposed in chip regions separated by front connection pads 132, a circuit layer (not illustrated), and a scribe lane SL are formed, and a region W2b removed by a subsequent grinding process (see FIG. 24).

A first adhesive tape sheet 1A may be attached to one surface of a first preliminary semiconductor structure ST1′. The first adhesive tape sheet 1A may include a substrate layer 21 and an adhesive layer 11. The substrate layer 21 and the adhesive layer 11 may be components corresponding to the substrate layer 20 and the adhesive layer 10 described with reference to FIGS. 1 to 3A.

The adhesive layer 11 may include a plurality of pattern portions PP defined by a non-patterned portion NP and an incision portion IP. The open portion OP of the plurality of pattern portions PP may be formed to be connected to the non-patterned portion NP in the second direction D2. The extension portion EP of the plurality of pattern portions PP may be formed to extend in the first direction D1 opposite to the second direction D2.

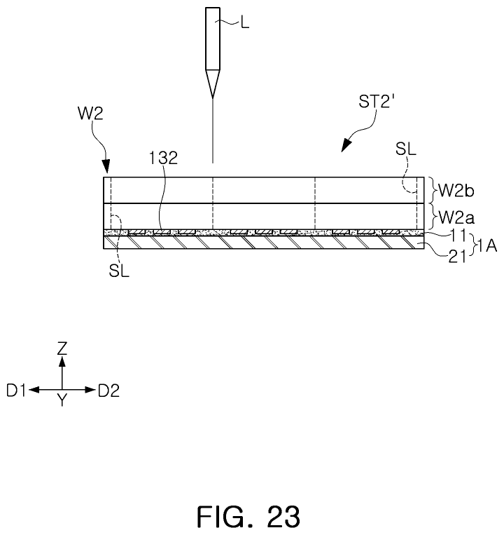

Referring to FIG. 21 and FIG. 23, a second preliminary semiconductor structure ST2′ may be formed by performing a first semiconductor process on the first preliminary semiconductor structure ST1′ (S2000).

The first semiconductor process may include dicing the first preliminary semiconductor structure ST1′ (S2000a). The dicing may be a laser stealth dicing process of cutting an internal portion of the semiconductor wafer W2 along the scribe lane SL using energy of a laser beam L.

Referring to FIG. 21 and FIG. 24, a third preliminary semiconductor structure ST3′ may be formed by performing a second semiconductor process on the second preliminary semiconductor structure ST2′ (S3000).

The second semiconductor process may include grinding and/or polishing one region W2a of the semiconductor wafer W2 to remove the region W2b.

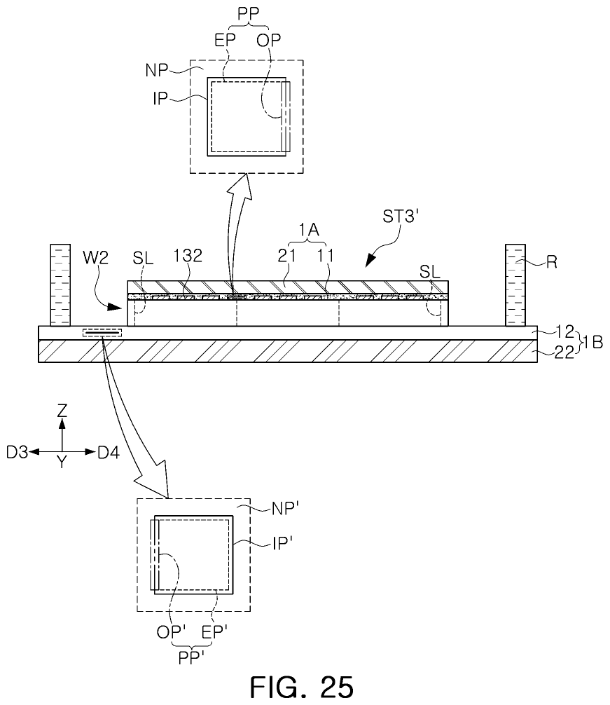

Referring to FIG. 21 and FIG. 25, the third preliminary semiconductor structure ST3′ may be provided on the second adhesive tape sheet 1B (S4000).

The providing the third preliminary semiconductor structure ST3′ (S4000) may include flipping the third preliminary semiconductor structure ST3′ and providing the structure on the second adhesive tape sheet 1B.

The second adhesive tape sheet 1B may include a substrate layer 22 and an adhesive layer 12. The substrate layer 22 and the adhesive layer 12 may be components corresponding to the substrate layer 20 and the adhesive layer 10 described with reference to FIGS. 1 to 3A.

The adhesive layer 12 may include a plurality of pattern portions PP′ defined by the non-patterned portion NP′ and the incision portion IP′. The open portion OP′ of the plurality of pattern portions PP′ may be formed to be connected to the non-patterned portion NP′ in the third direction D3. The extension portion EP′ of the plurality of pattern portions PP′ may be formed to extend in the fourth direction D4 opposite to the third direction D3.

Providing the third preliminary semiconductor structure ST3′ (S4000) may include providing a second direction (“D2” in FIG. 22) in which the open portion OP of the plurality of pattern portions PP of the adhesive layer 11 is connected to the non-patterned portion may be directed in the direction opposite to the third direction D3. From another perspective, the third preliminary semiconductor structure ST3′ may be provided such that the first direction (“D1” in FIG. 22) in which the extension portion EP of the adhesive layer 11 extends may be directed in the opposite direction to the fourth direction D4.

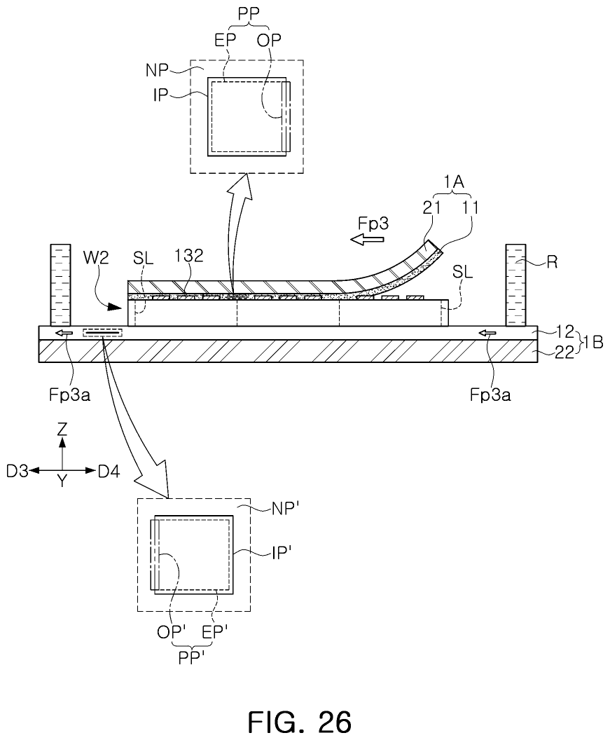

Referring to FIG. 21 and FIG. 26, the fourth preliminary semiconductor structure may be formed by performing a third semiconductor process on the third preliminary semiconductor structure ST3′ (S5000).

The third semiconductor process may include debonding the first adhesive tape sheet 1A from the third preliminary semiconductor structure ST3′ (S5000a).

Debonding the first adhesive tape sheet 1A (S5000a) may include applying a peeling force Fp3 in the third direction D3 to the first adhesive tape sheet 1A and peeling the first adhesive tape sheet 1A in a third direction D3. A portion Fp3a of the peeling force Fp3 may be transferred to the adhesive layer 12 of the second adhesive tape sheet 1B, and the portion Fp3a of the peeling force Fp3 may be applied in the third direction D3 to the adhesive layer 12 of the second adhesive tape sheet 1B. Accordingly, in the debonding process, the adhesive layer 12 of the second adhesive tape sheet 1B may have a strong adhesive force to the third preliminary semiconductor structure ST3′. Accordingly, cracks occurring at the edge of the third preliminary semiconductor structure ST3′ may be reduced by the debonding process. The first adhesive tape sheet 1A may be peeled relatively easily. The peeled first adhesive tape sheet 1A may be reused after being washed.

The fourth preliminary semiconductor structure may indicate a semiconductor wafer W2 from which the first adhesive tape sheet 1A has been removed.

Thereafter, a fourth semiconductor process may be performed on the fourth preliminary semiconductor structure (S6000).

The fourth semiconductor process may include applying pressure to the lower portion of the second adhesive tape sheet 1B such that the sheet may be bent upwardly, thereby individualizing the fourth preliminary semiconductor structure into a plurality of semiconductor chips along the scribe lane SL.

Thereafter, each of the individualized plurality of semiconductor chips may be attached to an adhesive tape sheet according to an example embodiment and a subsequent semiconductor packaging process may be performed thereon. In the subsequent semiconductor packaging process, the attaching the plurality of semiconductor chips to the adhesive tape sheet and the removing the adhesive tape sheet from each of the plurality of semiconductor chips may be substantially the same as described with reference to FIGS. 16 to 20.

According to the aforementioned example embodiments, an adhesive tape sheet having a plurality of patterns formed may be provided.

Specifically, an adhesive tape sheet including an adhesive film having a plurality of patterns having the same density and formed in the entirety of regions or different densities in each region may be provided.

Also, a method of manufacturing a semiconductor device using the adhesive tape sheet may be provided. When the adhesive tape sheet is used, cracks occurring at the edge of a semiconductor structure may be reduced, residue of an adhesive material may be reduced, and UV curing treatment for the adhesive tape sheet may be unnecessary. Accordingly, a semiconductor device having relatively high reliability may be provided.

While the example embodiments have been illustrated and described above, it will be configured as apparent to those skilled in the art that modifications and variations could be made without departing from the scope of the present disclosure as defined by the appended claims.

What is claimed is:

1. An adhesive tape sheet, comprising:
an adhesive film having a first region to which a semiconductor structure is attached and which vertically overlaps an edge of the semiconductor structure and a second region adjacent to the first region,
wherein the adhesive film comprises:
a non-patterned portion; and
a plurality of pattern portions defined by incision portions,
wherein at least a portion of the plurality of pattern portions comprise:
an open portion connected to the non-patterned portion in a first direction; and
an extension portion having at least a portion extending from the open portion in a second direction opposite to the first direction and defined by the incision portions,
wherein a first group of the plurality of pattern portions are disposed on the first region and a second group of the plurality of pattern portions are disposed on the second region, and
wherein a first density of the first group of the plurality of pattern portions and a second density of the second group of the plurality of pattern portions are different.

2. The adhesive tape sheet of claim 1, wherein the first density is greater than the second density.

3. The adhesive tape sheet of claim 1, wherein a ratio of the number of the plurality of pattern portions of the first group per area of the first region of the adhesive film is greater than a ratio of the number of the plurality of pattern portions of the second group per area of the second region of the adhesive film.

4. The adhesive tape sheet of claim 1, wherein a size of each of the plurality of pattern portions of the first group is smaller than a size of each of the plurality of pattern portions of the second group.

5. The adhesive tape sheet of claim 1, wherein the first region has an annular shape or a square annular shape.

6. The adhesive tape sheet of claim 1, wherein the second region is a region surrounded by the first region.

7. The adhesive tape sheet of claim 6, wherein the second region has a plurality of regions in which the plurality of pattern portions have different densities.

8. The adhesive tape sheet of claim 6,
wherein the adhesive tape sheet further comprises a third region surrounding the first region,
wherein a third group of the plurality of pattern portions are disposed on the third region, and
wherein a third density of the third group of the plurality of pattern portions is lower than the first density.

9. The adhesive tape sheet of claim 1, wherein the extension portions of each of the plurality of pattern portions comprises:
a first side and a second side extending in the second direction from both ends of the open portion, respectively, and opposing each other; and
a third side connecting the first side to the second side and opposing the open portion.

10. The adhesive tape sheet of claim 9, wherein a length of the open portion in the first direction is greater than a maximum length of the extension portion in the second direction.

11. The adhesive tape sheet of claim 9, wherein a length of the open portion in the first direction is less than a maximum length of the extension portion in the second direction.

12. The adhesive tape sheet of claim 1, wherein the extension portion of each of the plurality of pattern portions comprises:
a first side and a second side each extending in the second direction from both ends of the open portion and opposing each other; and
a third side and a fourth side each extending diagonally from ends of the first and second sides and connected on the open portion.

13. The adhesive tape sheet of claim 1, wherein the adhesive film includes an elastic polymer.

14. The adhesive tape sheet of claim 1, wherein the adhesive film includes at least one of a silicone elastomer, a polyurethane elastomer, an ethylene propylene diene monomer (EPDM) elastomer, a polybutadiene elastomer and a nitrile butadiene rubber.

15. The adhesive tape sheet of claim 1, further comprising:
a substrate film on the adhesive film.

16. An adhesive tape sheet, comprising:
an adhesive film comprising a non-patterned region and a pattern region having adhesion patterns defined by incision patterns,
wherein each of the incision patterns defines the adhesion patterns such that at least one side of each of the adhesion patterns is continuous with the non-patterned region and each of the other sides of the adhesion patterns is discontinuous with the non-patterned region, and
wherein the pattern region comprises:
a first region in which the adhesion patterns are disposed at a first density; and
a second region in which the adhesion patterns are disposed at a second density different from the first density.

17. The adhesive tape sheet of claim 16, wherein at least a portion of the adhesion patterns has an open polygonal shape having at least one open side or an open circular shape having at least one open side.

18. The adhesive tape sheet of claim 16, wherein at least a portion of the incision patterns extends along the other sides with a uniform thickness.

19. An adhesive tape sheet, comprising:
an adhesive film comprising a plurality of pattern portions defined by non-patterned portions and incision portions,
wherein at least a portion of the plurality of pattern portions of the adhesive film comprises:
an open portion connected to the non-patterned portion in a first direction; and
an extension portion extending from the open portion in a second direction opposite to the first direction and defined by the incision portions, and
wherein the adhesive film includes an elastic polymer.

20. The adhesive tape sheet of claim 19, wherein the extension portion of the at least a portion of the plurality of pattern portions comprises:
a first side and a second side extending in the second direction from both ends of the open portion, respectively, and opposing each other; and
a third side connecting the first side to the second side and opposing the open portion.
